(19) United States
(12) Patent Application Publication
(10) Pub. No.: US 2014/0239980 A1
(43) Pub. Date: Aug. 28, 2014

(54) CAPACITANCE TYPE OCCUPANT DETECTION SENSOR

(71) Applicant: DENSO CORPORATION, KARIYA-CITY (JP)

(72) Inventor: Kouji Ootaka, Toyohashi-city (JP)

(73) Assignee: DENSO CORPORATION, KARIYA-CITY (JP)

(21) Appl. No.: 14/189,111

(22) Filed: Feb. 25, 2014

(30) Foreign Application Priority Data
Feb. 27, 2013 (JP) 2013-37134

(51) Int. Cl. B60N 2/00; G01R 27/26

(52) U.S. Cl. CPC B60N 2/002; G01R 27/2605
USPC 324/679; 297/452.1

(57) ABSTRACT

A capacitance type occupant detection sensor includes (i) a capacitive sensor, (ii) a voltage application portion, (iii) a current detector, (iv) a capacitance detector, and (v) a determination portion. The capacitive sensor includes a detection electrode and is disposed to a seat. The voltage application portion applies a detection voltage to the detection electrode, and provides an electric field between the detection electrode and a reference electrode, which is applied with a reference voltage. The current detector detects a current, which is provided by the detection voltage, flowing through the detection electrode. The capacitance detector detects a capacitance between the detection electrode and the reference electrode. The determination portion determines an occupant. The capacitive sensor has a first charging electrode and a second charging electrode. The first charging electrode is disposed apart from the detection electrode and applied with a charging voltage from the voltage application portion.

### CROSS REFERENCE TO RELATED APPLICATION

This application is based on Japanese Patent Application No. 2013-37134 filed on Feb. 27, 2013, the disclosure of which is incorporated herein by reference.

### TECHNICAL FIELD

The present disclosure relates to a capacitance type occupant detection sensor determining an occupant based on a capacitance.

### BACKGROUND

A capacitance type occupant detection sensor is disclosed in JP-A-2008-111809 (corresponding to US 2008/0100425 A1), for example. In the capacitance type occupant detection sensor, an electrode is disposed into a seat of a vehicle. The capacitance type occupant detection sensor determines whether an occupant takes a seat in the vehicle or determines a type of the occupant (i.e., an adult person, a child sitting on a child restraint systems, or the like), based on a change of a capacitance between the electrode and a reference electrode (e.g., a vehicle body or the like). Hereinafter, the child restraint system is referred to as a CRS. Specifically, a relative permittivity of a detection object that is placed between electrodes is different each other. For, example, the relative permittivity of the air, the CRS, the adult person is about 1, between 2 and 5, and about 50, respectively. Therefore, the detected capacitance is changed, and the detection object is determined based on a capacitance change. It is possible that the capacitance change is detected by an impedance calculated from the amount of current and voltage between the electrodes.

The inventor of the present application has found the following.

Recently, a user of a vehicle often brings a portable device (or a mobile device) such as a mobile phone, a tablet terminal, or the like into the vehicle. Therefore, it may be required that the portable equipment should be charged in the vehicle so as to improve convenience.

### SUMMARY

It is an object of the present disclosure to provide a capacitance type occupant detection sensor that detects an occupant and charges a device of a portable device or the like to be charged.

According to an aspect of the present disclosure, a capacitance type occupant detection sensor including (i) a capacitive sensor, (ii) a voltage application portion, (iii) a current detector, (iv) a capacitance detector, and (v) a determination portion is provided. The capacitive sensor includes a detection electrode and is disposed to a seat of a vehicle. The voltage application portion applies a detection voltage to the detection electrode, and provides an electric field between the detection electrode and a reference electrode, which is applied with a reference voltage. The current detector detects a current, which is provided by the detection voltage, flowing through the detection electrode. The capacitance detector detects a capacitance between the detection electrode and the reference electrode based on the detection voltage and the current. The determination portion determines an occupant based on the capacitance. The capacitive sensor has a first charging electrode and a second charging electrode. The first charging electrode is disposed apart from the detection electrode and applied with a charging voltage from the voltage application portion. The second charging electrode is disposed apart from the first charging electrode in parallel and applied with the reference voltage. When the first charging electrode is applied with the charging voltage, the first charging electrode and the second charging electrode are capacitively coupled with a device to be charged that is opposed to the first charging electrode and the second charging electrode through a seat surface of the seat.

According to the above capacitance type occupant detection sensor, it is possible that the capacitive sensor detects an occupant and in addition, it is possible that the capacitive sensor charges the device to be charged.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a drawing illustrating a configuration of a capacitance type occupant detection sensor of a first embodiment;

FIG. 2 is a plan view illustrating a disposing state of the capacitance type occupant detection sensor of the first embodiment;

FIG. 3 is a sectional view taken along line III-III of FIG. 2, and illustrating a configuration of a capacitive sensor of the first embodiment;

FIG. 4 is a drawing illustrating a detailed configuration of the capacitance type occupant detection sensor of the first embodiment;

FIG. 5 is a drawing illustrating an occupant determination of the first embodiment;

FIG. 6 is a drawing illustrating a charging circuit of the first embodiment;

FIG. 7 is a drawing illustrating a detailed configuration of the capacitance type occupant detection sensor of a second embodiment;

FIG. 8 is a flowchart illustrating an example of a control of the second embodiment;

FIG. 9 is a drawing illustrating a configuration of the capacitance type occupant detection sensor of a third embodiment;

FIG. 10 is a sectional view taken along line X-X of FIG. 9, and illustrating a configuration of the capacitance type occupant detection sensor of the third embodiment; and

FIG. 11 is a drawing illustrating a seat in another embodiment of the third embodiment.

### DETAILED DESCRIPTION

Embodiments of the present disclosure will be described with reference to the drawings. Incidentally, identical parts or similar parts in the following embodiments are denoted by identical symbols. It should be noted that the drawings may be conceptual diagrams, and therefore, a shape or a configuration of each part may not correspond to an actual shape. In the following embodiment, it is supposed that the capacitive sensor is placed to an assistant driver seat, for example.

### First Embodiment

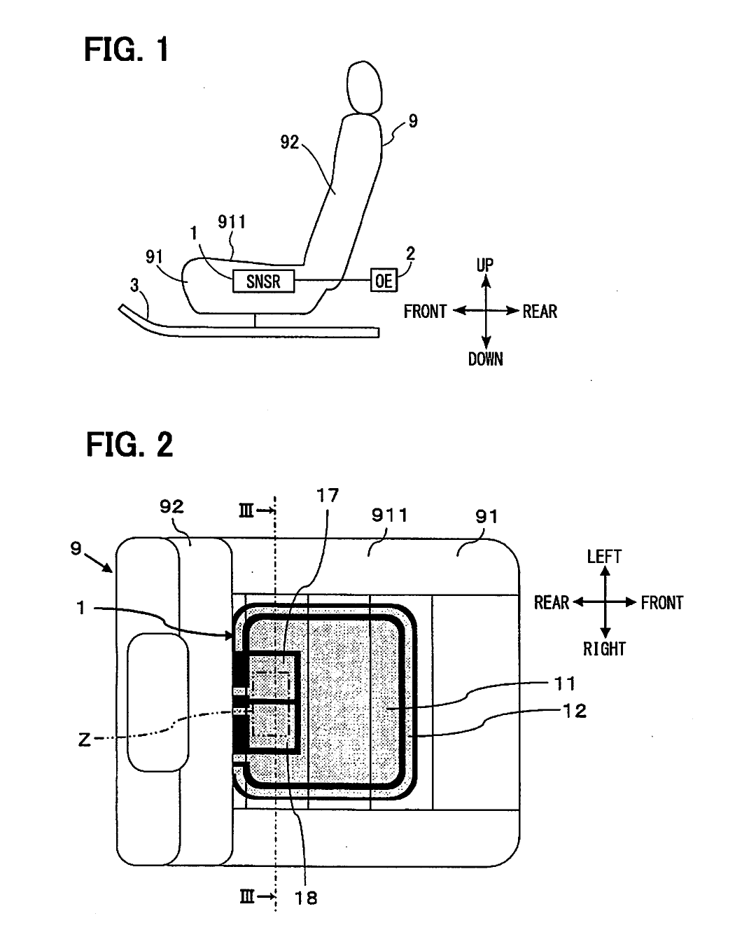

A capacitance type occupant detection sensor of a first embodiment includes a capacitive sensor 1 and an occupant detection ECU 2 as described in FIG. 1. The capacitive sensor 1 corresponds to a film sensor mat, and an electrode is disposed therein. The capacitive sensor 1 is disposed in a seat portion 91 (e.g., within a cushion) of the seat 9 of a vehicle. The seat 9 has the seat portion 91 with a seat surface 911, on which the occupant sits, and a seat back 92. The seat back 92 is disposed at a back side (corresponding to a rear side) of the seat portion 91 of the vehicle. The capacitive sensor 1 is placed substantially parallel to the seat surface 911.

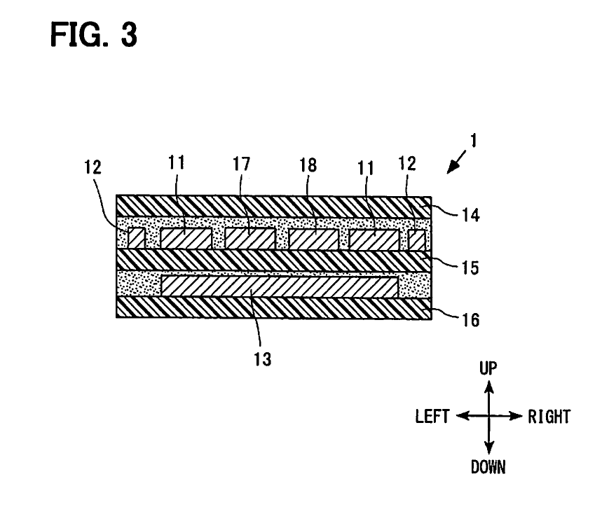

Specifically, the capacitive sensor 1, as described in FIG. 2 and FIG. 3, has a main electrode 11, a sub electrode 12, a guard electrode 13, film members 14 to 16, a first charging electrode 17, and a second charging electrode 18. The main electrode 11 corresponds to a detection electrode. The main electrode 11 is a plate-like conductive member, and is disposed above the film member 15. A rear center portion of the main electrode 11 in the present embodiment has a u-shape slot (or a depressed portion) toward a front direction when the main electrode 11 is viewed from an above side of the seat 9 (with reference to FIG. 2).

The sub electrode 12 is a plate-like conductive member, and is disposed apart from the main electrode 11 in parallel. The sub electrode 12 is placed along the main electrode 11 so that the sub electrode 12 is adjacent to the main electrode 11 on the film member 15. The sub electrode 12 is placed at the edge of the capacitive sensor 1. The film member 14 is disposed above the main electrode 11 and the sub electrode 12. Therefore, the main electrode 11 and the sub electrode 12 are placed between the film member 14 and the film member 15.

The guard electrode 13 is a plate-like conductive member, and is arranged on an opposite side (corresponding to a down side of the vehicle) of the seat surface 911 from the main electrode 11. In other words, the main electrode 11 is placed between the seat surface 911 and the guard electrode 13. Therefore, the guard electrode 13 is opposed to the main electrode 11 through the film member 15. The film member 16 is disposed below the guard electrode 13. Thus, the guard electrode 13 is placed between the film member 15 and the film member 16. The film members 14 to 16 are made from an insulating material (e.g., PET: polyethylene terephthalate) and, for example, an adhesive agent is included between the film members 14 to 16.

The first charging electrode 17 is a plate-like conductive member, and is disposed apart from the main electrode 11 in parallel. The first charging electrode 17 is disposed within the u-shape slot at the rear center portion of the main electrode 11. The second charging electrode 18 is a plate-like conductive member, and is disposed apart from the first charging electrode 17 in parallel. The second charging electrode 18 is disposed adjacent to the first charging electrode 17 within the u-shape slot at the rear center portion of the main electrode 11. The capacitive sensor 1 as a whole has a substantially square shape. The first charging electrode 17 and the second charging electrode 18 are disposed between the film member 14 and the film member 15.

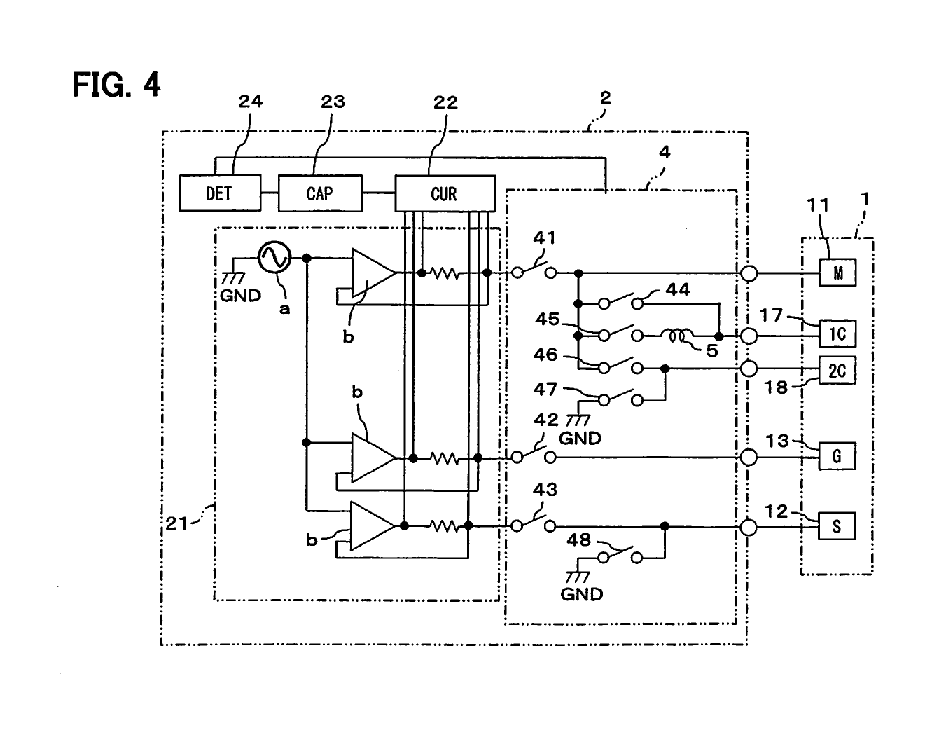

The occupant detection ECU 2 is an electronic control unit having a CPU, a memory, or the like. As described in FIG. 4, the occupant detection ECU 2 has a voltage application portion 21, a current detector 22, a capacitance detector 23, a determination portion 24, and a switch 4, as configurations and functions.

The voltage application portion 21 is connected to a vehicle grounding GND (corresponding to a reference voltage), and is connectable to each of the electrodes 11 to 13, 17, 18 of the capacitive sensor 1. The voltage application portion 21 includes an AC power supply a and multiple operational amplifiers b. The voltage application portion 21 is applicable an AC voltage (corresponding to a detection voltage) to each of the electrodes 11 to 13, 17, 18 through the switch 4. The operational amplifiers b correspond to drivers so that voltage equal to the detection voltage is applied to each of the electrodes 11 to 13, 17, 18. In an occupant detection mode described below, each of the electrodes 11 to 13, 17, 18 provides an electric field with a vehicle body 3 (corresponding to a reference electrode). Incidentally, the vehicle body 3 is a body part of the vehicle, and configures an electrode, so that the vehicle body 3 has the reference voltage (corresponding to the vehicle grounding GND).

The current detector 22 is a current sensor, and detects a current flowing through each of the electrodes 11 to 13, 17, 18 by voltage application due to the voltage application portion 21. The capacitance detector 23, based on a voltage (corresponding to the detection voltage) and a current, calculates a capacitance between predetermined electrodes. The voltage application portion 21 applies the detection voltage to each of the electrodes 11 to 13, 17, 18. The current detector 22 detects the current. Incidentally, the capacitance is calculated based on an imaginary component (i.e., a susceptance) of an impedance (i.e., an admittance) in a current pathway in a voltage application. The imaginary component is calculated from a phase shift of a voltage and a current. The capacitance detector 23 in the present embodiment calculates a susceptance and a conductance in the current pathway in the voltage application. Detection of the capacitance in the current pathway corresponds to a calculation of the impedance in the current pathway.

The determination portion 24 determines whether an occupant exists or not based on a detection result of the capacitance detector 23 and a predetermined threshold value (corresponding to an occupant determination threshold value). In addition, the determination portion 24 determines whether the occupant is an adult person or the CRS, based on a detection result of the capacitance detector 23 and another predetermined threshold value (corresponding to an adult determination threshold value). The determination portion 24 controls connections of each of the switches 41 to 48 in the switch 4, so that the determination portion 24 switches an operation mode to either an occupant detection mode, a wet detection mode, or a charging mode. Each of the operation modes will described below in detail.

The switch 4 includes a first switch 41, a second switch 42, a third switch 43, a fourth switch 44, a fifth switch 45, a sixth switch 46, a seventh switch 47, and an eighth switch 48. The first switch 41 is an electromagnetic switch. One end of the first switch 41 is connected to the voltage application portion 21, and the other is connected to the main electrode 11. The second switch 42 is an electromagnetic switch. One end of the second switch 42 is connected to the voltage application portion 21, and the other is connected to the guard electrode 13. The third switch 43 is an electromagnetic switch. One end of the third switch 43 is connected to the voltage application portion 21, and the other end is connected to the sub electrode 12.

The fourth switch 44 is an electromagnetic switch. One end of the fourth switch 44 is connected to the other end of the first switch 41, and the other of the fourth switch 44 is connected to the first charging electrode 17. The fifth switch 45 is an electromagnetic switch. One end of the fifth switch 45 is connected to the other end of the first switch 41, and the other end of the fifth switch 45 is connected to the first charging electrode 17 through a coil 5. The sixth switch 46 is an electromagnetic switch. One end of the sixth switch 46 Is connected to the other end of the first switch 41, and the other end of the sixth switch 46 is connected to the second charging electrode 18. The seventh switch 47 is an electromagnetic switch. One end of the seventh switch 47 is connected to the vehicle grounding GND, and the other end of the seventh switch 47 is connected to the second charging electrode 18. The eighth switch 48 is an electromagnetic switch. One end of the eighth switch 48 is connected to the vehicle grounding GND, and the other end of the eighth switch 48 is connected to the sub electrode 12. The coil 5 is disposed between the first charging electrode 17 and the voltage application portion 21.

(Occupant Detection Mode)

In the occupant detection mode, the determination portion 24 causes the first switch 41, the second switch 42, the third switch 43, the fourth switch 44, and the sixth switch 46 to be a connection states, and causes the other switches 45, 47, 48 to be a disconnection state. Accordingly, an electrical potential of the main electrode 11 is equal to the electrodes 12, 13, 17, 18, so that the electric field is provided between the vehicle body 3 and each of the electrodes 11 to 13, 17, 18. The guard electrode 13 has the same electric potential with the main electrode 11 below the main electrode 11, so that the guard electrode 13 prevents the main electrode 11 from forming the electric field with the vehicle body 3 below the main electrode 11 without going through the seat surface 911 of the seat 9. Therefore, the guard electrode 13 is provided so that the main electrode 11 forms the electric field on the seat 9 more surely.

The sub electrode 12 is an electrode to mainly detect a wet state of the seat 9 in the wet detection mode. The sub electrode 12 has the same potential with the main electrode 11 in the occupant detection mode, so that the sub electrode 12 provides the electric field with the vehicle body 3, similar to the main electrode 11. The capacitance is used for an occupant detection in the occupant detection mode. It may be prevented that an electrical flux line, which goes out from an edge (or, an end) of the main electrode 11, spreads to the vehicle body 3 without going through the seat 9 and the occupant. Thus, the sub electrode 12 prevents the electrical flux line of the main electrode 11 from leaking in a horizontal direction.

In the occupant detection mode, the current detector 22 detects currents flowing through the main electrode 11, the sub electrode 12, the first charging electrode 17, and the second charging electrode 18. Specifically, the current detector 22 detects a current (corresponding to a main current) flowing through the first switch 41, and another current (corresponding to a sub current) flowing through the third switch 43. The main current corresponds to a current when the main electrode 11, the first charging electrode 17, and the second charging electrode 18 are supposed to configure a single electrode. In the present embodiment, since a single electric current sensor for measuring current is used, the main current and the sub current are measured sequentially.

The capacitance detector 23 calculates the impedance of the current pathway between electrodes based on a sum of the main current and the sub current, and the detection voltage. The capacitance detector 23 calculates the susceptance and the conductance from the calculated impedance. The susceptance corresponds to the capacitance, and therefore a calculation of the susceptance corresponds to a detection of the capacitance.

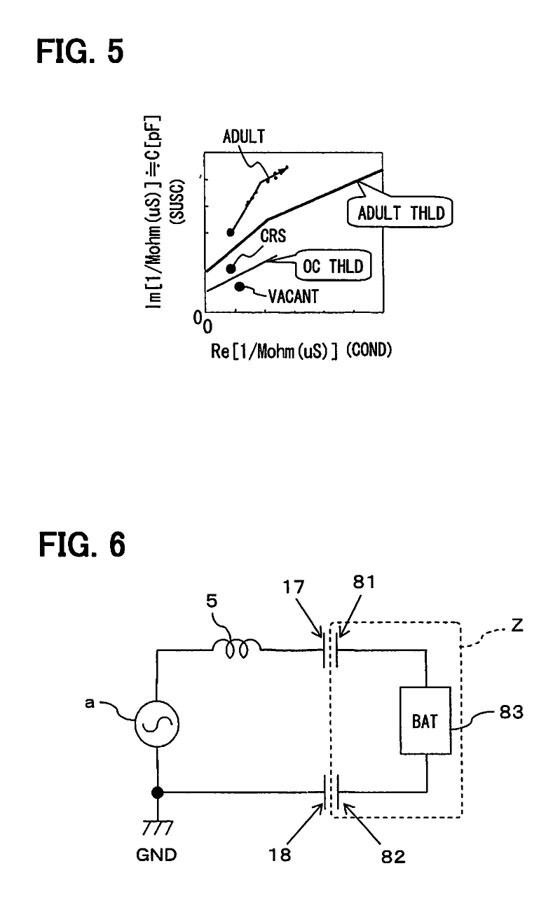

The determination portion 24, as described in FIG. 5, compares the predetermined threshold values (corresponding to the occupant determination threshold value and the adult determination threshold value) with the susceptance and the conductance, and determines whether the occupant exists and what type of the occupant exists. When a calculated value calculated by the determination portion 24 is equal or more than the occupant determination threshold value, the determination portion 24 determines that the occupant exists. When the calculated value is less than the occupant determination threshold value, the determination portion 24 determines that the occupant does not exist (or a vacant seat). When the determination portion 24 has determined that the occupant exists, and the calculated value is equal or more than the adult determination threshold value, the determination portion 24 determines that the occupant corresponds to the adult person. When the determination portion 24 has determined that the occupant exists, and the calculated value is less than the adult determination threshold value, the determination portion 24 determines that the occupant corresponds to a child (or corresponding to the CRS). Although the occupant detection may be possible to be performed only by the susceptance, by considering the conductance, a determination accuracy will be improved. Incidentally, it may be possible to use a well-known method to determine an occupant using the capacitance.

The determination portion 24 transmits the determination result to the airbag ECU (not shown). When the determination result of an assistant driver's seat indicates that the adult person takes a seat, the airbag ECU permits an inflation of an airbag at the assistant driver's seat in a collision. When the determination result of the assistant driver's seat indicates that the seat is vacant or the child (or the CRS) takes a seat, the airbag ECU forbids the inflation of the airbag at the assistant driver's seat.

(Wet Detection Mode)

In the wet detection mode, the determination portion 24 causes the first switch 41, the second switch 42, the fourth switch 44, the sixth switch 46, and the eighth switch 48 to be the connection state, and causes the other switches 43, 45, 47 to be the disconnection state. Accordingly, the sub electrode 12 is connected to the vehicle grounding GND, so that the electric field is provided between the sub electrode 12 and each of the main electrode 11, the first charging electrode 17, and the second charging electrode 18.

The current detector 22 detects the main current flowing through the first switch 41. The capacitance detector 23 calculates the impedance from the main current and the detection voltage, and detects the capacitance. The determination portion 24, based on the capacitance, determines whether the seat portion 91 of the seat 9 is wet. When the determination portion 24 determines that the seat 9 is wet, the determination portion 24 forbids the occupant determination and provides the occupant with information. Incidentally, the determination portion 24 may determine the occupant with using a predetermined occupant determination threshold value for the wet state, when the seat 9 is wet.

(Charging Mode)

In the charging mode, the determination portion 24 causes the first switch 41, the second switch 42, the third switch 43, the fifth switch 45, and the seventh switch 47 to be the connection state, and causes the other switches 44, 46, 48 to be the disconnected state. Accordingly, the voltage application portion 21 applies the detection voltage (corresponding to a charging voltage) to the first charging electrode 17 through the coil 5. The second charging electrode 18 is connected to the vehicle grounding GND.

When a portable device Z (corresponding to a device to be charged) such as a mobile phone or the like is disposed at a charging portion (corresponding to a predetermined portion) corresponding to the first charging electrode 17 and the second charging electrode 18 of the seat surface 911, a capacitance coupling is provided between the portable device Z and each of the first charging electrode 17 and the second charging electrode 18.

Conceptually, as described in FIG. 6, in the charging mode, the first charging electrode 17, the second charging electrode 18, the AC power supply a, the coil 5, and the portable device Z configure a charging circuit. The first charging electrode 17 forms the electric field with a charging electrode 81 of the portable device Z. The second charging electrode 18 forms the electric field with a charging electrode 82 of the portable device Z. In other words, the charging electrodes 81, 82 of the device to be charged is electrically disposed opposed to the charging electrodes 17, 18 of the capacitive sensor 1 respectively, and an electric circuit is provided. An electric power is transmitted from the voltage application portion 21 to the battery 83, which is disposed between the charging electrodes 17, 18, through the capacitive sensor 1 by a so-called electric field resonance method (or an electric field coupling method), and the battery 83 is charged. As described above, in the charging mode, the portable device Z putted above the charging portion of the seat 9 is charged contactlessly by the capacitance type occupant detection sensor.

According to the capacitance type occupant detection sensor in the first embodiment, it is possible to detect the occupant, and to charge the device to be charged such as the portable device Z or the like. In addition, the main electrode 11, the sub electrode 12, and the guard electrode 13 are applied by the detection voltage in the occupant detection mode and the charging mode. Accordingly, each of the electrodes 11 to 13 has the same potential with the first charging electrode 17, and it is prevented that the first charging electrode 17 forms the electric field with the other electrodes or the vehicle body 3. Thus, it is possible to configure the charging circuit more accurately. In the first embodiment, the determination portion 24 switches between the operation modes (corresponding to the occupant detection mode, the wet detection mode, and the charging mode) at each predetermined time. An order of the operation mode may be set arbitrarily. For example, the operation mode may be switched in the order of the wet detection mode, the occupant detection mode, and the charging mode. A condition (corresponding to a predetermined condition) to switch the operation mode may be set arbitrarily.

In the first embodiment, the first charging electrode 17 and the second charging electrode 18 are disposed at the end portion within the seat portion 91 in a side of the seat back 92. Therefore, the predetermined portion where the device to be charged is disposed in charging corresponds to the end portion (corresponding to the rear end portion of the seat surface 911) of the seat surface 911 in the side of the seat back 92. Generally, the end portion of the seat surface 911 in the side of the seat back 92 has the seat back 92 in a rear direction of the vehicle, and the end portion is positioned lower than a front portion of the seat surface 911 from a point of view of a sitting comfortability. Accordingly, it is possible that a disposing state of the device to be charged is stabilized to the predetermined portion. Generally, right and left end portions of the seat surface 911 are elevated upwardly, and therefore, it may be possible that the device to be charged is disposed to the predetermined portion (corresponding to a rear center end portion of the vehicle) more stably.

In addition, in the occupant detection mode in the first embodiment, each of the charging electrodes 17, 18 has the same potential with the main electrode 11, and the current flowing through the main electrode 11 and each of the charging electrodes 17, 18 is measured as the main current. Thus, in the present embodiment, the charging electrodes 17, 18 also function as the main electrode 11. Accordingly, it is possible that an electrode surface area functioning as the main electrode 11 is assured, and that the occupant detection accuracy is accurately maintained.

In addition, in the charging mode, since the charging voltage applied to the first charging electrode 17 is set to the detection voltage for the occupant detection, it may not be required to separately provide a configuration for charging to the voltage application portion 21 or the like. Therefore, it is possible to reduce increase of a manufacturing cost.

### Second Embodiment

The capacitance type occupant detection sensor in the second embodiment is different from the first embodiment in a configuration of the switch 4 and a control process of the determination portion 24. The symbols identical in the first embodiment indicate a similar configuration in the first embodiment, and the above description will be referenced.

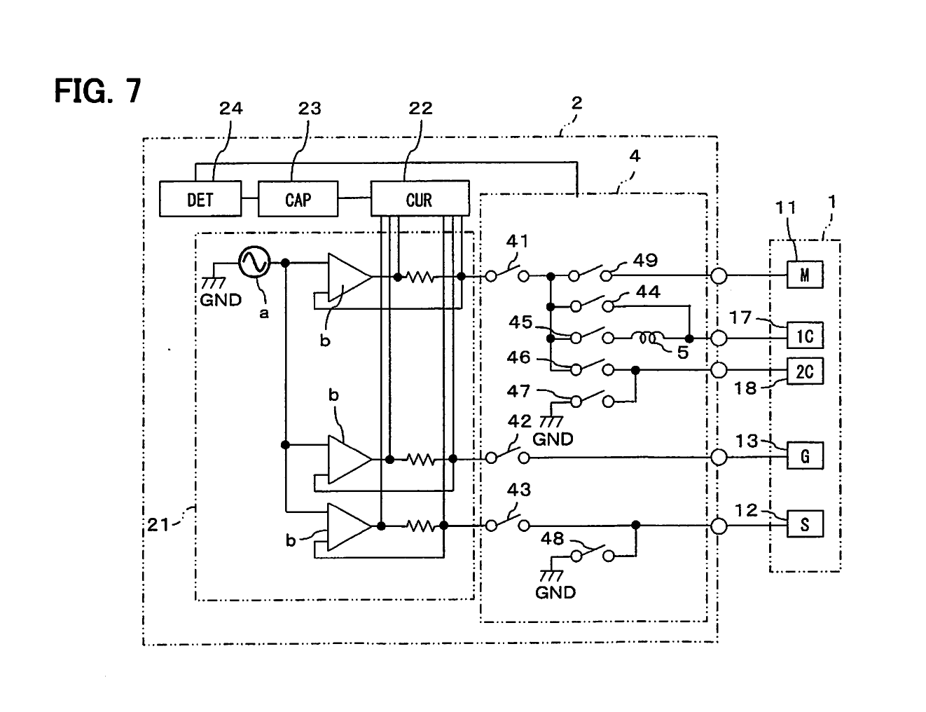

The switch 4, as described in FIG. 7, includes a ninth switch 49 between the first switch 41 and the main electrode 11, in addition to a configuration of the first embodiment. The determination portion 24 causes the ninth switch 49 to be the connection state in the occupant detection mode and the wet detection mode, and to be the disconnection state in the charging mode.

In the charging mode, the current detector 22 detects a current flowing through the first charging electrode 17 and the second charging electrode 18 except the main electrode 11. In other words, the current detector 22 detects current that an influence of the main electrode 11 is excluded from the main current. Detected current values are different between a case when the capacitance coupling is formed between the charging electrodes 17, 18 and the portable device Z, and another case when the capacitance coupling is not formed. It is possible to accurately detect the difference between the detected current values by disconnecting the ninth switch 49. Therefore, it is possible that, in the charging mode, the determination portion 24 determines whether a charging is performed or not (corresponding to whether the portable device Z is placed above the predetermined portion or not) based on a detection current of the current detector 22. The determination portion 24 in the second embodiment, in the charging mode, determines whether the device (e.g., the portable device Z) to be charged is placed or not. In other words, it may be possible to describe that the occupant detection ECU 2 includes a charging determination portion (not shown). Herein, the charging determination portion determines whether the device to be charged is charged or not based on a current flowing through the first charging electrode in the charging mode.

The determination portion 24 sets the operation mode to the occupant detection mode firstly and determines the occupant. After the predetermined time has been passed, the determination portion 24 switches from the occupant detection mode to the wet detection mode, and determines whether the seat 9 is wet or not. When the determination portion 24 has determined that the occupant exists after the wet detection mode, the determination portion 24 does not switch the operation mode to the charging mode, and repeats the operation mode into the occupant detection mode again. When the determination portion 24 has determined that the occupant exists after the wet detection mode, it is forbidden to switch to the charging mode.

When the determination portion 24 has determined that the occupant does not exist after the wet detection mode, the determination portion 24 switches the operation mode into the charging mode. In the charging mode, the determination portion 24 determines whether the device to be charged is placed or not at each predetermined time (or alternatively, the determination portion 24 may consecutively determine whether the device to be charged is placed or not). When the determination portion 24 has determined that the device to be charged is placed, the determination portion 24 continues the charging mode. When the determination portion 24 has determined that the device to be charged is not placed, the determination portion 24 switches the operation mode into the occupant detection mode.

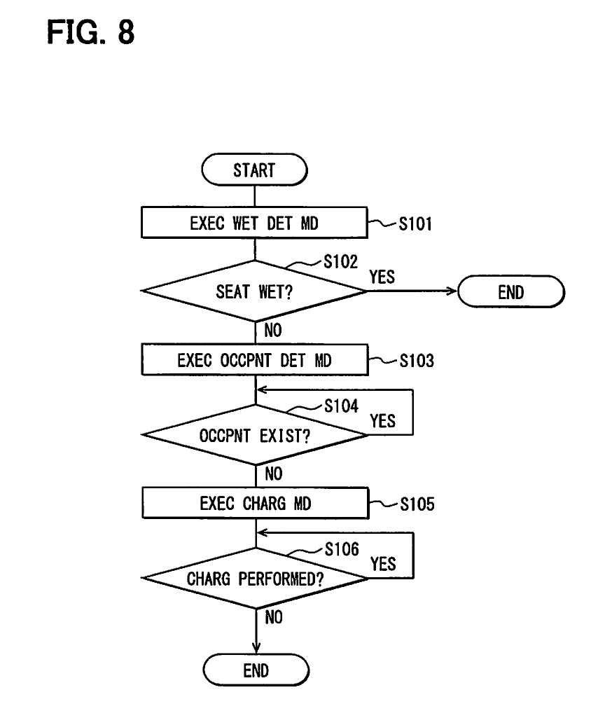

A control process starting from the wet detection mode will be exemplified briefly with reference to FIG. 8. Firstly, the determination portion 24 sets the operation mode into the wet detection mode (at S101). Secondly, the determination portion 24 determines whether the seat 9 has been wet or not (at S102). When the seat 9 is wet (corresponding to “YES” at S102), the determination portion 24 performs a control process in a wet state. The control process in the wet state corresponds to notification to a driver, a stop of the occupant detection, or the occupant detection in the wet state, for example.

When the seat 9 is not wet (corresponding to “NO” at S102), the determination portion 24 switches the operation mode into the occupant detection mode (S103). When the determination portion 24 does not detect the occupant (corresponding to “NO” at S104), the determination portion 24 switches the operation mode into the charging mode (at S105). When the device to be charged is not placed at the predetermined portion (corresponding to “NO” at S106), the control process ends and the control process is restarted after a predetermined time. When the device to be charged is placed at the predetermined portion (corresponding to “YES” at S106), the charging mode continues. The determination portion 24 may be set so as to switch from the charging mode to the occupant detection mode after a predetermined time (at S103).

According to the second embodiment, in addition to the technical effect of the first embodiment, it may be possible to charge the device to be charged continuously in a case where the device to be charged is placed at the predetermined portion. When the device to be charged is fully charged, the current value detected by the current detector 22 is different from the current value during charging. Therefore, based on the current value differences, the determination portion 24 may detect an end of charging, and may switch from the charging mode to the occupant detection mode or the wet detection mode. Alternatively, the determination portion 24 may determine that the device to be charged is not placed at the predetermined portion when the end of charging has been detected, for example.

### Third Embodiment

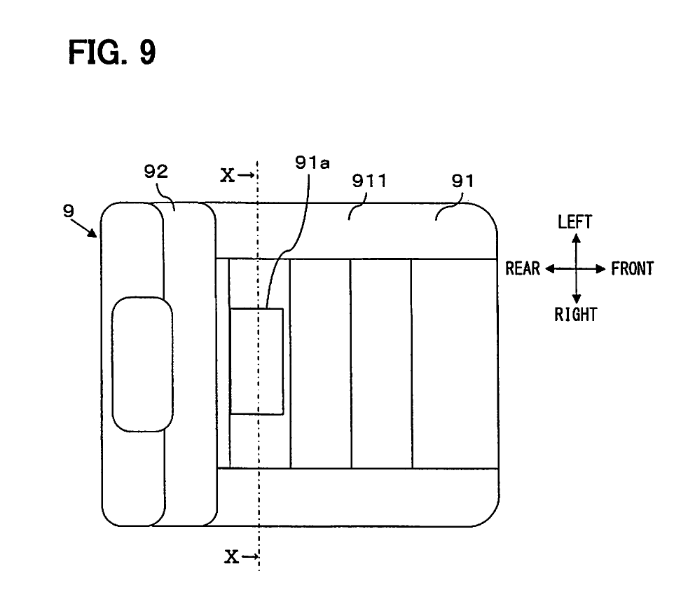

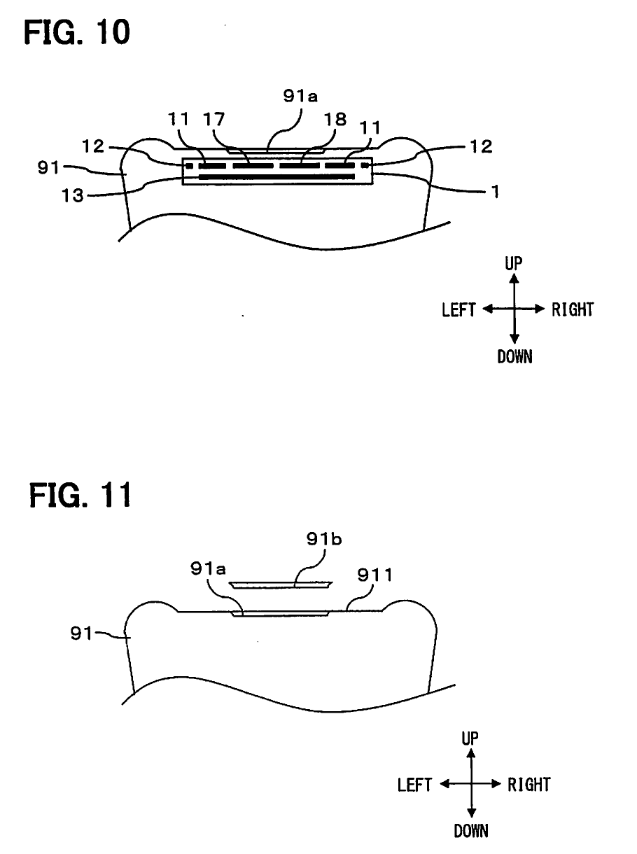

The capacitance type occupant detection sensor of the third embodiment, as described in FIG. 9 and FIG. 10, is different from the first embodiment in that the seat portion 91 of the seat 9 has a depression 91a. The symbols identical in the first embodiment indicate a similar configuration in the first embodiment, and the above description will be referenced.

The seat portion 91 includes the depression 91a, which is concaved downwardly, at the end portion of the seat surface 911 adjacent to the seat back 92 (in other words, at the rear end portion of the seat surface 911). The depression 91a is provided at the predetermined portion of the seat portion 91, i.e., a position corresponding to the first charging electrode 17 and the second charging electrode 18 of the capacitive sensor 1. More specifically, the depression 91a is placed opposed to the first charging electrode 17 and the second charging electrode 18. When the capacitive sensor 1 is viewed from an upper position of the vehicle, the first charging electrode 17 and the second charging electrode 18 are included in the depression 91a. Thus, in the present embodiment, a bottom surface of the depression 91a is larger than a sum of areas of the first charging electrode 17 and the second charging electrode 18.

According to the third embodiment, since the depression 91a is provided at the seat portion 91, it is possible that the user places the device to be charged such as the portable device Z or the like to the depression 91a. Since the depression 91a is provided at the position corresponding to the first charging electrode 17 and the second charging electrode 18, the device to be charged is placed above the depression 91a and the device to be charged may be chargeable. In addition, even when the device to be charged receives an acceleration or an vibration during driving and moves, the device to be charged contacts a side wall of the depression 91a, and the device to be charged is prevented to move outside the depression 91a.

As described above, according to the third embodiment, in addition to the technical effect of the first embodiment, it may be possible that the user easily realize a position of the device to be charged, and the device to be charged may be prevented to be off from an appropriate position. According to the third embodiment, it may be possible to charge the device to be charged more surely during driving. The end portion of the seat portion 91 adjacent to the seat back 92 corresponds to a small contact area with a human body when the occupant takes a seat. In the present embodiment, since the depression 91a is provided at the end portion of the seat portion 91 adjacent to the seat back 92, it may be possible to reduce an influence on a sitting comfortability when the occupant sits on the seat 9. As described above, from a viewpoint of the sitting comfortability, the depression 91a may be provided at a position of the seat surface 911 that does not contact (or unlikely contact) the occupant during sitting. The position of the seat surface 911 corresponds to a rear center end portion or a front center end portion of the seat surface 911, for example.

Alternatively, the seat portion 91, as described in FIG. 11, may include a fitting portion 91b, which is separated from the depression 91a and fits with the depression 91a. The fitting portion 91b is a seat member corresponding to a depressed shape of the depression 91a, and has a volume corresponding to a volume of the depression 91a. The fitting portion 91b is made from a material (e.g., a cover and a cushion) same with the seat portion 91. The fitting portion 91b is detachable from the depression 91a. The top surface of the fitting portion 91b is configured to have the same height of the seat surface 911 around the depression 91a when the fitting portion 91b fits with the depression 91a. According to this configuration, when charging is not performed, it is possible to fill the depression 91a with the fitting portion 91b, and it is possible to suppress an influence on the sitting comfortability of the seat 9.

### Another Embodiment

The present disclosure is not limited to the above embodiments. For example, when the device to be charged is charged, an arrangement position (corresponding to the predetermined position) i.e., the arrangement position of the first charging electrode 17 and the second charging electrode 18, may be another position (e.g., a center of the seat portion 91) other than the above described position.

Alternatively, in the charging mode, the main electrode 11, the sub electrode 12, or the guard electrode 13 may be an open state (or in a condition where the main electrode 11, the sub electrode 12, or the guard electrode 13 is separated from the AC power supply a and the reference electrode). For example, in the charging mode, a switch corresponding to the second switch 42, the third switch 43, or the ninth switch 49 may be in the disconnection state. According to this configuration, the device to be charged may be charged in the charging mode. Incidentally, a charging efficiency when the first charging electrode 17 has a potential same with the other electrodes in the charging mode is better than a condition where the main electrode 11, the sub electrode 12, or the guard electrode 13 is in the open state, since it is possible to suppress a coupling between electrodes that are in the open state and the first charging electrode 17.

As described in FIG. 4, the current detector 22 may detect current (corresponding to a current flowing through the second switch 42) flowing through the guard electrode 13, and the determination portion 24 may determine a malfunction such as a disconnection or the like based on the current. Alternatively, it may be enough that the current detector 22 detects the main current for the occupant detection and the sub current for the wet detection. Therefore, the current detector 22 may not detect the current flowing through the second switch 42. Alternatively, it may be enough that the switch 4 is a circuit configuration switchable between the operation modes, and it may be enough that each of the switches 41 to 49 is switchable between the connection state and the disconnection state of two points. Alternatively, the capacitive sensor 1 may not have the sub electrode 12 and the guard electrode 13. Alternatively, a shape of the main electrode 11 may be corrugated.

According to the present disclosure, a capacitance type occupant detection sensor including (i) a capacitive sensor, (ii) a voltage application portion, (iii) a current detector, (iv) a capacitance detector, and (v) a determination portion is provided. The capacitive sensor includes a detection electrode and is disposed to a seat of a vehicle. The voltage application portion applies a detection voltage to the detection electrode, and provides an electric field between the detection electrode and a reference electrode, which is applied with a reference voltage. The current detector detects a current, which is provided by the detection voltage, flowing through the detection electrode. The capacitance detector detects a capacitance between the detection electrode and the reference electrode based on the detection voltage and the current. The determination portion determines an occupant based on the capacitance. The capacitive sensor has a first charging electrode and a second charging electrode. The first charging electrode is disposed apart from the detection electrode and applied with a charging voltage from the voltage application portion. The second charging electrode is disposed apart from the first charging electrode in parallel and applied with the reference voltage. When the first charging electrode is applied with the charging voltage, the first charging electrode and the second charging electrode are capacitively coupled with a device to be charged. The device to be charged is opposed to the first charging electrode and the second charging electrode through a seat surface of the seat.

According to the capacitance type occupant detection sensor in the present disclosure, an electric power is transmitted from the voltage application portion to the battery of the device to be charged through the capacitive sensor by an electric field resonance method (or an electric field coupling method), and the battery is charged. Therefore, according to the present configuration, it is possible to contactlessly charge the device to be charged above a seat. According to the present configuration, it is possible that the capacitive sensor detects an occupant and in addition, it is possible that the capacitive sensor charges the device to be charged. Incidentally, each of the above reference voltage may be different each other.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A capacitance type occupant detection sensor comprising:
a capacitive sensor including a detection electrode and disposed to a seat of a vehicle;
a voltage application portion applying a detection voltage to the detection electrode, and providing an electric field between the detection electrode and a reference electrode, which is applied with a reference voltage;
a current detector detecting a current, which flows through the detection electrode due to application of the detection voltage to the detection electrode;
a capacitance detector detecting a capacitance between the detection electrode and the reference electrode based on the detection voltage and the current detected by the current detector; and
a determination portion determining an occupant based on the capacitance detected by the capacitance detector,
wherein the capacitive sensor further includes:
a first charging electrode, which is disposed apart from the detection electrode and applied with a charging voltage from the voltage application portion; and
a second charging electrode, which is disposed apart from the first charging electrode in parallel and applied with the reference voltage, and
wherein when the first charging electrode is applied with the charging voltage, the first charging electrode and the second charging electrode are capacitively coupled with a device to be charged that is opposed to the first charging electrode and the second charging electrode through a seat surface of the seat.

2. The capacitance type occupant detection sensor according to claim 1, wherein
the charging voltage corresponds to the detection voltage.

3. The capacitance type occupant detection sensor according to claim 1,
wherein the determination portion switches based on a predetermined condition between an occupant detection mode, in which the occupant is detected, and a charging mode, in which the device to be charged is charged,
wherein the detection electrode is applied with the detection voltage in the occupant detection mode,
wherein the first charging electrode is applied with the detection voltage in the occupant detection mode and the charging mode,
wherein the second charging electrode is applied with the detection voltage in the occupant detection mode, and is applied with the reference voltage in the charging mode, and
wherein the determination portion determines the occupant based on the capacitance between the reference electrode and each of the detection electrode, the first charging electrode, and the second charging electrode.

4. The capacitance type occupant detection sensor according to claim 3, wherein
the detection electrode is applied with the detection voltage in the occupant detection mode and the charging mode.

5. The capacitance type occupant detection sensor according to claim 3, wherein
when the determination portion determines that the occupant exists in the occupant detection mode, the determination portion forbids switching to the charging mode.

6. The capacitance type occupant detection sensor according to claim 3, wherein
the determination portion determines whether the device to be charged is placed or not based on the current flowing through the first charging electrode in the charging mode.

7. The capacitance type occupant detection sensor according to claim 1,
wherein the seat includes
a seat portion having the seat surface on which the occupant sits, and
a seat back placed in a rear side of the seat portion, and
wherein the first charging electrode and the second charging electrode are disposed at an end of the seat portion in the rear side of the seat portion.

8. The capacitance type occupant detection sensor according to claim 1,
wherein the seat includes
a seat portion having the seat surface where the occupant sits on, and
a seat back placed in a rear side of the seat portion, and
wherein the seat portion has a depression, which is depressed corresponding to a position of the first charging electrode and the second charging electrode.

9. The capacitance type occupant detection sensor according to claim 1,
wherein the capacitive sensor includes a guard electrode, which is opposed to the detection electrode and applied with the detection voltage, and
wherein the detection electrode is disposed between the seat surface and the guard electrode.

10. The capacitance type occupant detection sensor according to claim 1,
wherein the determination portion switches based on a predetermined condition between an occupant detection mode, in which the occupant is detected, and a wet detection mode, in which a wet state of the seat is detected,
wherein the detection electrode is applied with the detection voltage in the occupant detection mode and the wet detection mode, and
wherein the capacitive sensor includes a sub electrode, which is disposed apart from the detection electrode in parallel, applied with the detection voltage in the occupant detection mode and applied with the reference voltage in the wet detection mode.

11. The capacitance type occupant detection sensor according to claim 1,
wherein the determination portion switches based on a predetermined condition between an occupant detection mode, in which the occupant is detected, a wet detection mode, in which a wet state of the seat is detected, and a charging mode, in which the device to be charged is charged,
wherein the detection electrode is applied with the detection voltage in the occupant detection mode, the wet detection mode, and the charging mode,
wherein the capacitive sensor includes a guard electrode and a sub electrode,
wherein the guard electrode is opposed to the detection electrode, and is applied with the detection voltage in the occupant detection mode, the wet detection mode, and the charging mode,
wherein the detection electrode is disposed between the seat surface and the guard electrode, and
wherein the sub electrode is disposed apart from the detection electrode in parallel, applied with the detection voltage in the occupant detection mode and the charging mode, and applied with the reference voltage in the wet detection mode.

12. The capacitance type occupant detection sensor according to claim 6, wherein
the reference electrode is connected with a vehicle grounding, and
the detection electrode, the first charging electrode, and the second charging electrode are arranged in a same plane, which is parallel to the seat surface of the seat.

13. The capacitance type occupant detection sensor according to claim 12, wherein
the determination portion refers
an occupant determination threshold value to determine whether the occupant exists, and
an adult determination threshold value to determine whether the occupant is an adult person.
